(19) United States
(12) Patent Application Publication
(10) Pub. No.: US 2021/0097380 A1
(43) Pub. Date: Apr. 1, 2021

(54) SINGLE TRANSISTOR CAPABLE OF USING BOTH NEURON AND SYNAPTIC DEVICES, AND A NEUROMORPHIC SYSTEM USING IT

(71) Applicant: Korea Advanced Institute of Science and Technology, Daejeon (KR)

(72) Inventors: Yang-Kyu CHOI, Daejeon (KR); Joon-Kyu HAN, Daejeon (KR); Gyeong Jun YUN, Daejeon (KR)

(73) Assignee: Korea Advanced Institute of Science and Technology, Daejeon (KR)

(21) Appl. No.: 17/037,444

(22) Filed: Sep. 29, 2020

(30) Foreign Application Priority Data
Oct. 1, 2019 (KR) 10-2019-0121331
Dec. 16, 2019 (KR) 10-2019-0167547

(51) Int. Cl. G06N 3/063; H01L 29/78; H01L 29/792; H01L 27/1157

(52) U.S. Cl. CPC G06N 3/0635; H01L 27/1157; H01L 29/792; H01L 29/7841

(57) ABSTRACT

The present invention relates to a single transistor implementing a neuromorphic system capable of performing neuron and synaptic operations through the single transistor including a floating body layer and a charge storage layer and being implemented by a neuron device and a synaptic device which are co-integrated on the same plane, and the neuromorphic system using the same, and forms the single transistor including a hole barrier material layer formed on a substrate and including a hole barrier material or an electron barrier material, the floating body layer formed on the hole barrier material layer, a source and a drain formed on opposite sides of the floating body layer, a gate insulating layer formed on the floating body layer and including an oxide layer and the charge storage layer, and a gate formed on the gate insulating layer.

### CROSS-REFERENCE TO RELATED APPLICATIONS

This application claims priority under 35 U.S.C. § 119 to Korean Patent Application No. 10-2019-0167547 filed on Dec. 16, 2019, and Korean Patent Application No. 10-2019-0121331 filed on Oct. 1, 2019, in the Korean Intellectual Property Office, the disclosures of which are incorporated by reference herein in their entireties.

### BACKGROUND

Embodiments of the present invention described herein relate to a single transistor usable as a neuron device and a synaptic device and a neuromorphic system using the same, and more particularly, to a technology that enables neuron and synaptic operations through a single transistor including a floating body layer and a charge storage layer and implements a neuromorphic system by co-integrating neuron and synaptic devices on the same plane using the single transistor.

In the era of the 4th industrial revolution, research on artificial intelligence systems has been actively conducted. Among them, as an alternative that is capable of overcoming a limitation of the conventional von Neumann method, which consumes enormous energy in artificial intelligence operation, a neuromorphic computing system takes the spotlight.

The neuromorphic computing is a method of implementing artificial intelligence operations by imitating a human brain in hardware. The human brain performs very complex functions, but energy consumed by the brain is only 20 W. Accordingly, the neuromorphic computing imitates the human brain structure itself to perform artificial intelligence operations of association, inference, and recognition, which are superior to conventional computing, with ultra-low power.

A neuromorphic chip or a neuromorphic system that enables neuromorphic computing to operate consists of neurons and synapses, which is the same as that of the human brain consisting of neurons, which are nerve cells, and synapses, which are connection sites. The neurons play a role of integrating current signals transmitted from a pre-synapse and transmitting a spike-shaped voltage signal to a post-synapse when a certain threshold is exceeded. Currently, the neurons are implemented as CMOS-based complex circuits. The circuit-based neuron is implemented by accumulating charges in a membrane capacitor and transferring the charges to the post-synapse using a comparator circuit when the charges reach a threshold value or more.

Accordingly, the neurons occupy a layout area of up to 20000F², and are limited in terms of integration.

The synapses memorize strength (weight) based on a correlation of the spikes expressed by the neurons and the strength or weight is adjusted through a process of potentiation and depression, from case to case. A resistive random access memory (RRAM) or memristor-based synaptic device has been studied as the synaptic device, but there are problems in reliability and process compatibility with CMOS technology, and therefore, a silicon-based 3-terminal flash memory synaptic device has been actively studied. The related synaptic device adjusts the weight of the synapse depending on an amount of charges stored in a charge storage layer of a gate of a transistor.

The conventional neuromorphic system has an array of neuron circuits and synaptic devices as described above as a basic component and after being separately manufactured, the array of the neuron circuits and synaptic devices are connected on a printed circuit board (PCB) through wire bonding.

Therefore, there is a limit in terms of integration, and energy loss in a process of signal transmission between the neurons and synapses, and interconnection delay and interference in the wire metal occur to limit energy efficiency and speed of the neuromorphic system. Accordingly, there is a need for a technology capable of improving the above-described limiting factors.

### SUMMARY

Embodiments of the present invention provide a single transistor including a floating body layer for neuron operation and a charge storage layer in a gate for synaptic operation to be usable as neuron and synaptic devices and a highly neuromorphic system in which the neuron device and the synaptic device are co-integrated on the same plane using the same process using the single transistor. Therefore, a degree of integration, energy consumption, and speed of the neuromorphic system may be improved compared to the conventional neuromorphic system, in which a neuron circuit and a synaptic device array are manufactured through different processes and then are connected through wire bonding on a printed circuit board (PCB).

However, the technical problems to be solved by the present invention are not limited to the above problems, and may be variously extended without departing from the technical spirit and scope of the present invention.

According to an exemplary embodiment, a single transistor usable as neuron and synaptic devices includes a hole barrier material layer formed on a substrate and including a hole barrier material or an electron barrier material, a floating body layer formed on the hole barrier material layer, a source and a drain formed on opposite sides of the floating body layer, a gate insulating layer formed on the floating body layer and including an oxide layer and a charge storage layer, and a gate formed on the gate insulating layer.

The hole barrier material layer may be formed of one of buried oxide, buried n-well in a case of a p-type body, a buried p-well in a case of an n-type body, buried SiC, and buried SiGe.

The floating body layer may accumulate holes generated by impact ionization and may be formed of one of silicon, germanium, silicon germanium, and group 3-5 compound semiconductor.

The floating body layer may have one structure of a planar-type floating body layer, a fin-type floating body layer, and a nanowire-type or nanosheet-type floating body.

The floating body layer may be formed on the substrate in a horizontal direction or a vertical direction.

The single transistor usable as neuron and synaptic devices may further include a lower substrate formed below the floating body layer, and the lower substrate may operate as a back gate.

The source and drain may be formed on left and right sides of the floating body layer in a case of a horizontal transistor and may be formed above and below the floating body layer in a case of a vertical transistor, and may be formed of one of n-type silicon, p-type silicon, and metal silicide.

The source and drain formed of the n-type silicon or the p-type silicon may be formed by one of diffusion, solid-phase diffusion, epitaxial growth, selective epitaxial growth, ion implantation, and post-heat treatment.

The source and drain formed of the metal silicide may be formed of one of erbium (Er), ytterbium (Yb), samarium (Sm), yttrium (Y), gadolium (Gd), turbule (Tb), cerium (Ce), platinum (Pt), lead (Pb), and iridium (Ir), and dopant segregation may be used to improve junction.

The source and drain may be formed in an asymmetrical structure of a concentration gradient to block a sneaky path of an array of the neuron and synapse.

The gate insulating layer may include two oxide layers positioned on opposite sides of the charge storage layer, or include one oxide layer positioned on one side of the charge storage layer.

The gate may have a gate-all-around structure surrounding the entire floating body layer.

The single transistor may not include the hole barrier material layer when having the gate-all-around structure.

The gate may have a structure of a multiple-gate.

The single transistor, when a current signal is applied to the source and drain and the signal above a certain level is integrated, may output a voltage signal in a spike form from the source and drain.

The single transistor, when a voltage signal is applied to the gate, may output a current signal that changes depending on an amount of charges stored in the charge storage layer from the source and drain.

According to an exemplary embodiment, a highly-integrated neuromorphic system includes a single transistor usable as a neuron device and a synaptic device and is implemented using the single transistor as the neuron device and the synaptic device.

According to an exemplary embodiment, a highly-integrated neuromorphic system includes a single transistor usable as a neuron device and a synaptic device and the neuron device and the synaptic device are co-integrated on the same plane using the same process and are connected using an interconnect metal to implement the neuromorphic system.

The neuromorphic system may be used for on-chip learning by inserting an additional circuit that changes a weight of the synaptic device.

The neuromorphic system may include one additional component of a resistor, a capacitor, and another transistor, in addition to the single transistor.

According to an exemplary embodiment, a single transistor usable as neuron and synaptic devices includes a source and a drain formed in an asymmetrical structure having a concentration gradient to block a sneaky path of a neuron and synapse array, a floating body layer formed between the source and the drain and performing a neuron operation, a gate insulating layer formed on the floating body layer and including a charge storage layer performing a synaptic operation, and a gate formed on the gate insulating layer.

### BRIEF DESCRIPTION OF THE FIGURES

FIGS. 1A and 1B are cross-sectional views of a single transistor usable as a neuron device and a synaptic device according to an embodiment of the present invention;

FIGS. 2A and 2B illustrate electron microscopy images of a single transistor usable as a neuron device and a synaptic device according to an embodiment of the present invention;

FIGS. 3A and 3B are diagrams for explaining a neuron operation and a synaptic operation of a single transistor usable as a neuron device and a synaptic device according to an embodiment of the present invention;

FIGS. 4A and 4B are graphs showing results of electrical measurements that implement neuron operation and synaptic operation using a vertical transistor usable as a neuron device and a synaptic device according to an embodiment of the present invention;

FIG. 5 illustrates a configuration of an array of neurons and synapses in a neuromorphic system according to an embodiment of the present invention;

FIG. 6 illustrates a circuit diagram of a neuromorphic system using a single transistor usable as a neuron device and a synaptic device according to an embodiment of the present invention;

FIG. 7 illustrates a structure in which neurons and synapses are simultaneously implemented and connected on the same plane using a vertical transistor usable as a neuron device and a synaptic device according to an embodiment of the present invention; and

FIGS. 8 and 9 are graphs of electrical measurements of a neuromorphic system implemented using a vertical transistor usable as a neuron device and a synaptic device according to an embodiment of the present invention.

### DETAILED DESCRIPTION

Hereinafter, embodiments according to the present invention will be described in detail with reference to the accompanying drawings. However, the present invention is not restricted or limited by the embodiments. In addition, the same reference numerals shown in each drawing denote the same member.

In addition, terms used herein are terms used to properly express preferred embodiments of the present invention, which may vary depending on the intention of viewers or operators, or customs in the field to which the present invention belongs. Accordingly, definitions of these terms should be made based on the contents throughout the present specification.

Before describing embodiments according to the present invention in detail, one term is summarized. Whereas a general floating body or a floating body layer is a channel of a 4-electrode (gate, source, drain, body)-based electric field transistor, a floating body or floating body layer refers to a channel of a transistor of 3-electrode (gate, source, drain). Typically, it is widely used in devices on a silicon-on-insulator (SOI) substrate. In this case, a gate on a channel may control channel potential of all or part of a top of the channel exposed through a thin gate insulating layer. However, because the lower part of the channel is adjacent to buried oxide, it is difficult to control a potential of a lower part of the channel although a voltage is applied through a back-gate, which is the SOI substrate, due to the very thick buried oxide. Therefore, the SOI device cannot effectively control the potential of the lower part of the channel, resulting in an undesirable floating body effect.

In a broad concept, an isolated channel of a gate-all-around (GAA) transistor, which is surrounded by the GAA, such as a nanowire or a nanosheet may be a floating body because a separate voltage is not applied to the body. However, in this case, the effect of the floating body cannot be alleviated because a channel potential is well controlled by the gate, due to the gate surrounding the entire channel and the very thin gate insulating layer.

Unlike a horizontal transistor, a vertical transistor is formed on a bulk silicon (bulk-Si) substrate, and thus it seems that there is no floating body in appearance, but it is not. For example, a channel is isolated by an n+ source and an n+ drain arranged vertically in a case of a p-type body or by a p+ source and a p+ drain to arranged vertically in a case of an n-type body, to form a floating body structure. Similarly, the channel is electrically insulated from the bulk-Si substrate to form the floating body by buried SiC or buried SiGe under a vertical protrusion.

Therefore, in the present invention, the floating body is used in the horizontal transistor and the vertical transistor.

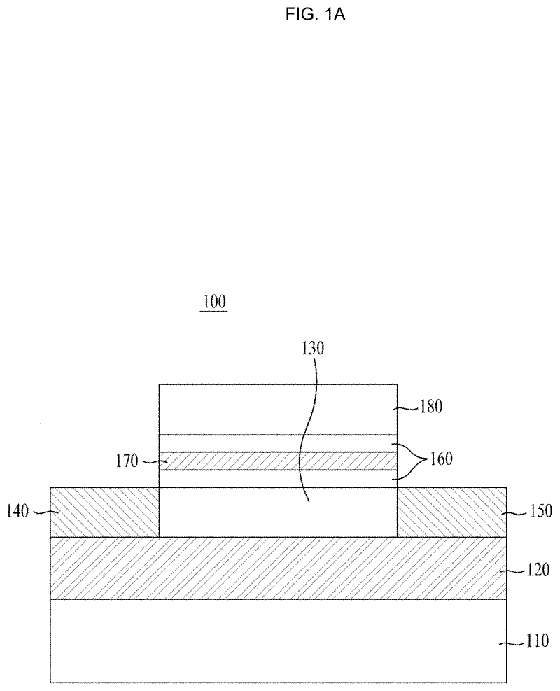

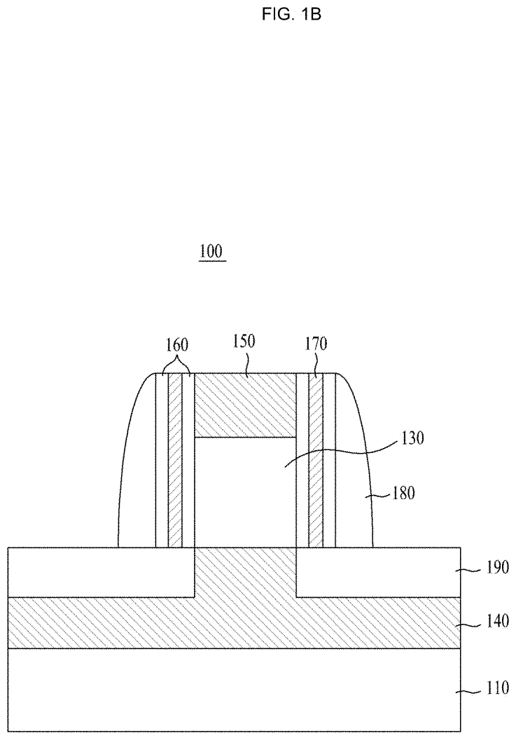

FIGS. 1A and 1B are cross-sectional views of a single transistor usable as a neuron device and a synaptic device according to an embodiment of the present invention.

In detail, FIG. 1A is a cross-sectional view of a horizontal transistor usable as a neuron device and a synaptic device according to an embodiment of the present invention and FIG. 1B is a cross-sectional view of a vertical transistor usable as a neuron device and a synaptic device according to an embodiment of the present invention.

Referring to FIGS. 1A and 1B, a single transistor 100 usable as a neuron device and a synaptic device according to an embodiment of the present invention includes a substrate 110, a hole barrier material layer 120, a floating body layer 130, a source 140, a drain 150, an oxide layer 160, a charge storage layer 170, a gate 180, and an insulating layer 190. Here, in the single transistor structure capable of performing both neuron operation and synaptic operation, a core structure enabling the neuron operation is the floating body layer 130, and a core structure enabling the synaptic operation is the charge storage layer 170.

Hereinafter, the single transistor 100 according to an embodiment of the present invention based on an n-channel device will be described.

Referring to FIG. 1A, the substrate 110 may act as a back gate applying a voltage bias and the hole barrier material layer 120 and the floating body layer 130 are sequentially disposed on the substrate 110.

According to an embodiment, the substrate 110 may represent a single crystal semiconductor substrate and may be formed of any one of silicon (Si), silicon germanium (SiGe), tensile silicon (strained Si), tensile silicon germanium (strained SiGe), silicon-on-insulator (SOI), silicon carbide (SiC), and a group 3-5 compound semiconductor.

The hole barrier material layer 120 is formed on the substrate 110 and includes a hole barrier material or an electron barrier material.

The hole barrier material layer 120 may be any one of buried oxide, buried n-well in a case of a p-type body, buried p-well in a case of an n-type body, buried SiC, and buried SiGe.

The floating body layer 130 is formed on the hole barrier material layer 120.

The floating body layer 130 may be formed on the hole barrier material layer 120 and may be formed of any one of silicon, germanium, silicon germanium, and a group 3-5 compound semiconductor. Further, holes generated by impact ionization are accumulated in the floating body layer 130 to enable neuron operation.

The floating body layer 130 may have a structure of any one of a planar-type floating body layer, a fin-type floating body layer, and a nanowire-type or a nanosheet-type floating body layer.

The floating body layer 130 may be formed in a horizontal direction on the substrate 110 like a horizontal transistor shown in FIG. 1A and may be formed on the substrate 110 in a vertical direction like a vertical transistor shown in FIG. 1B.

According to an embodiment, the single transistor 100 may further include a lower substrate formed below the floating body layer, and the lower substrate may operate as a back gate.

The source 140 and the drain 150 are formed on opposite sides of the floating body layer 130.

The source 140 and the drain 150 may be formed on left and right sides of the floating body layer 130 like the horizontal transistor shown in FIG. 1A and the source 140 and the drain 150 may be formed above and below the floating body layer 130 like the vertical transistor shown in FIG. 1B, and the source 140 and the drain 150 may be formed of any one of n-type silicon, p-type silicon, and metal silicide. Here, the source 140 and the drain 150 may have a different type from the floating body layer 130. For example, when the source 140 and drain 150 are p-type, the floating body layer 130 may be n-type, and when the source 140 and drain 150 are n-type, the floating body layer 130 may be p-type.

For example, the source 140 and the drain 150 formed of n-type silicon or p-type silicon may be formed by any one or more of diffusion, solid-phase diffusion, epitaxial growth, selective epitaxial growth, ion implantation, and post-heat treatment.

The source 140 and the drain 150 may exhibit an asymmetric structure of different doping concentrations and this kind of structure may be used to block a sneaky path of a neuron and synaptic array without a separate selector.

In another example, the source 140 and the drain 150 formed of metal silicide may include metal silicide formed of any one of erbium (Er), ytterbium (Yb), samarium (Sm), yttrium (Y), gadolium (Gd), turbule (Tb), cerium (Ce), platinum (Pt), lead (Pb), and iridium (Ir), and in this case, the transistor may be a Schottky barrier transistor. In addition, the source 140 and the drain 150 formed of metal silicide may use dopant segregation for improved junction, and the transistor using the dopant segregation may be a dopant segregation Schottky barrier transistor.

The gate insulating layers 160 and 170 are formed on the floating body layer 130 and include the oxide layer 160 and the charge storage layer 170.

The gate insulating layers 160 and 170 may include two oxide layers 160 positioned on opposite sides of the charge storage layer 170, or may include one oxide layer 160 positioned on one side of the charge storage layer 170.

The oxide layer 160 formed on the floating body layer 130 in the single transistor 100 according to an embodiment of the present invention may insulate the floating body layer 130 from the charge storage layer 170, may be called as a tunneling oxide layer, and may be formed any one of silicon oxide, nitride layer, aluminum oxide, hafnium oxide, hafnium oxynitride, zinc oxide, zirconium oxide, hafnium zirconium oxide (HZO), or any combination thereof.

The charge storage layer 170 is on the oxide layer 160 and has different weights depending on an amount of charges stored therein to enable a synaptic operation. The charge storage layer 170 may be formed of any one of materials having poly-silicon, amorphous silicon, metal oxide, silicon nitride, silicon nano-crystal, and metal oxide nano crystal.

Another oxide layer 160 formed on the charge storage layer 170 may insulate the charge storage layer 170 from the gate 180, may be called as a blocking oxide, and may be formed of any one of silicon oxide, nitride layer, aluminum oxide, hafnium oxide, hafnium oxynitride, zinc oxide, zirconium oxide, hafnium zirconium oxide (HZO), or any combination thereof.

Meanwhile, according to an embodiment, either one or both of the two oxide layers 160 may not exist.

The gate 180 is formed on the gate insulating layers 160 and 170.

The gate 180 may be formed on the oxide layer 160 and may be formed of any one of n-type polysilicon, p-type polysilicon, and metal. The metals may be formed of one of aluminum (Al), molybdenum (Mo), magnesium (Mg), chromium (Cr), palladium (Pd), platinum (Pt), nickel (Ni), titanium (Ti), gold (Au), tantalum (Ta), tungsten (W), silver (Ag), tin (TiN), tantalum nitride (TaN), or any combination thereof.

The gate 180 may have a gate-all-around structure surrounding the entire floating body layer 130. Accordingly, when the single transistor 100 according to an embodiment of the present invention is formed in a gate-all-around structure, the hole barrier material layer 120 is not included.

The gate 180 may represent a multiple-gate structure.

Referring to FIG. 1B, the insulating layer 190 insulates the source 140 and drain 150 and the gate 180 of a vertical transistor, and may be formed of a material forming the oxide layer 160.

The single transistor 100 usable as the neuron device and synaptic device according to an embodiment of the present invention may have a structure of a gate-all-around (GAA) transistor in which the floating body layer 130 has a nanowire or nanosheet structure and the oxide layer 160, the charge storage layer 170, and the gate 180 surrounds the floating body layer 130. Here, the channel of the single transistor 100 may be isolated by the n+ source and the n+ drain vertically arranged in the case of the p-type body or by the p+ source and the p+ drain vertically arranged in the case of the n-type body, to allow holes formed by impact ionization to be trapped without the hole barrier material layer 120, and therefore the hole barrier material layer 120 may not exist.

In particular, because the general vertical transistor as shown in FIG. 1B has the gate-all-around (GAA) transistor structure, the hole barrier material layer 120 does not exist.

In the single transistor 100 usable as the neuron device and the synaptic device according to an embodiment of the present invention shown in FIGS. 1A and 1B, as an example, when a current signal is applied to the source 140 and the drain 150, signals more than a certain level may be integrated and a voltage signal in a spike form may be output from the source 140 and the drain 150, and as another example, when a voltage signal is applied to the gate 180, the source 140 and the drain 150 may output a current signal that changes depending on the amount of charges stored in the charge storage layer 170.

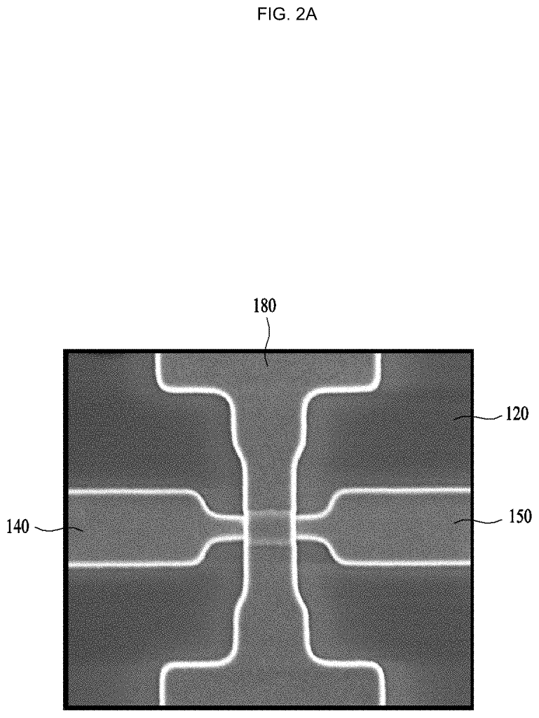

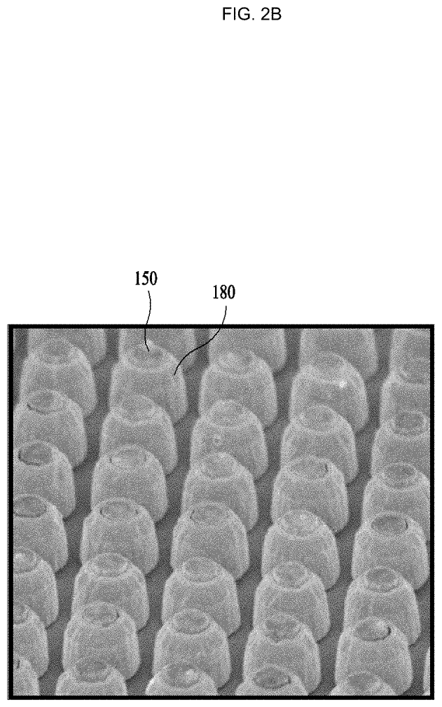

FIGS. 2A and 2B illustrate electron microscopy images of a single transistor usable as a neuron device and a synaptic device according to an embodiment of the present invention.

Specifically, FIG. 2A shows a scanning electron microscope (SEM) image of a horizontal transistor capable of performing a neuron operation and a synaptic operation, which is actually manufactured according to an embodiment of the present invention and FIG. 2B shows a scanning electron microscope (SEM) image of a vertical transistor capable of performing a neuron operation and a synaptic operation, which is actually manufactured according to an embodiment of the present invention.

Referring to FIG. 2A, an electron microscope image for the hole barrier material layer 120, the source 140, the drain 150, and the gate 180 of the horizontal transistor capable of performing the neuron operation and the synaptic operation, which is actually manufactured may be confirmed.

In addition, referring to FIG. 2B, an electron microscope image for the drain 150 and the gate 180 of the vertical transistor capable of performing the neuron operation and the synaptic operation, which is actually manufacture may be confirmed.

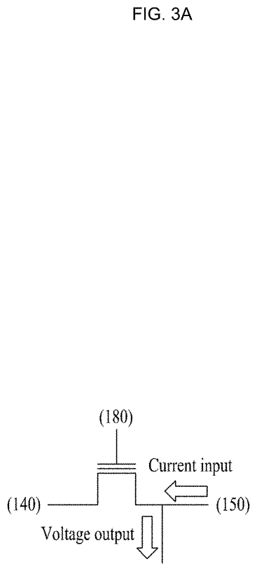

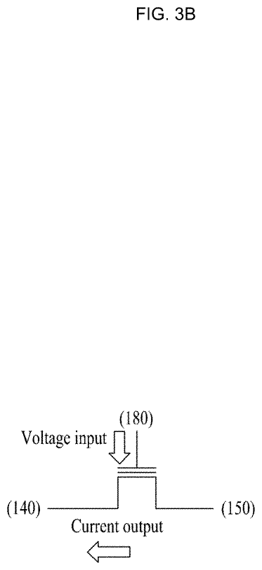

FIGS. 3A and 3B are diagrams for explaining a neuron operation and a synaptic operation of a single transistor usable as a neuron device and a synaptic device according to an embodiment of the present invention.

In detail, FIG. 3A is a diagram illustrating a neuron operation method of a single transistor capable of performing a neuron operation and a synaptic operation according to an embodiment of the present invention, and FIG. 3B is a diagram illustrating a synaptic operation method of a single transistor capable of performing a neuron operation and a synaptic operation according to an embodiment of the present invention.

Referring to FIG. 3A, when a current signal is input to the source 140 or the drain 150 and signals more than a certain level are integrated, a voltage signal in a spike form is output from the source 140 or the drain 150. Here, a frequency of the spike varies depending on a magnitude of the input current signal. For example, when the magnitude of the input current signal is large, more frequent spikes occur.

Referring to FIG. 3B, a voltage signal is input through the gate 180 and a current signal is output to the source 140 or the drain 150. Here, the magnitude of the current signal varies depending on the amount of charges stored in the charge storage layer 170, which means the weight of the synaptic device. For example, when the weight is large, a larger current signal is output for the same voltage input signal.

The weight may be changed through a potentiation or depression process in which a voltage in a form of a pulse is applied to the gate 180.

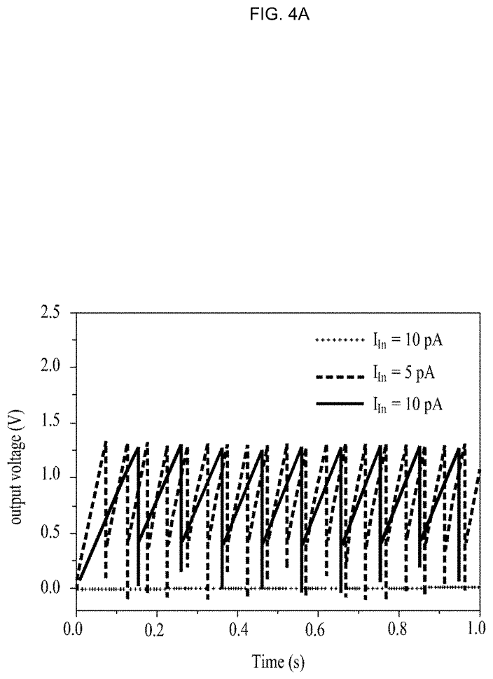

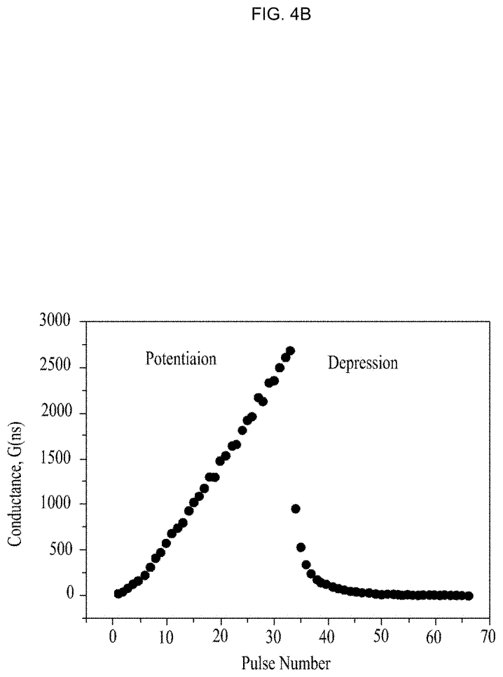

FIGS. 4A and 4B are graphs showing results of electrical measurements that implement neuron operation and synaptic operation using a vertical transistor usable as a neuron device and a synaptic device according to an embodiment of the present invention.

In detail, FIG. 4A is a graph of results of electrical measurements that implement neuron operation using the operation method of FIG. 3A in the vertical transistor capable of performing the neuron operation and the synaptic operation, which is actually manufactured, according to an embodiment of the present invention and FIG. 4B is a graph of results of electrical measurements that implement synaptic operation using the operation method of FIG. 3B in the vertical transistor capable of performing the neuron operation and the synaptic operation, which is actually manufactured, according to an embodiment of the present invention.

Referring to FIG. 4A, it may be confirmed that, when a current signal of a certain level or more is input, an output voltage in a spike form occurs. In addition, it may be confirmed that characteristics of a typical neuron device in which a spike frequency increases as a magnitude of the input current Iₗₙ increases are shown.

An experiment of FIG. 4A was measured using a vertical transistor having a vertical nanowire diameter of 400 nm, and a gate voltage of −1V was applied to enable neuron operation. The transistor capable of performing neuron operation may change spike frequency for a fixed input current as the gate voltage is changed. In addition, exhibition characteristics of the neuron in which the spike is expressed when the current is input may be implemented, and the spike may be controlled not to be expressed at a specific gate voltage to implement inhibitory characteristics of the neuron. Therefore, the inhibitory characteristics of the neuron may be characteristics appearing in biological neurons, and energy consumption may be minimized by operating only necessary neurons.

Referring to FIG. 4B, it may be seen that electrical conductivity (conductance) of the synaptic device shows characteristics of a typical synaptic device that are changed by potentiation and depression pulses.

An experiment of FIG. 4B was measured using a vertical transistor having a vertical nanowire diameter of 400 nm, and a potentiation pulse having an amplitude of −11V and a time of 100 us and a depression pulse having an amplitude of 11V and a time of 10 us were used. In addition, a gate voltage of 2V and a drain voltage of 1V were used as a reading voltage for extracting electrical conductance.

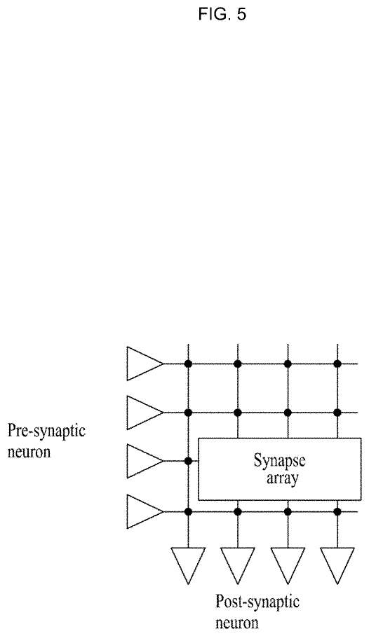

FIG. 5 illustrates a configuration of an array of neurons and synapses in a neuromorphic system according to an embodiment of the present invention.

When a single transistor usable as a neuron device and a synaptic device according to an embodiment of the present invention is used, reconfigurable neuromorphic system in which the transistor is used as the neuron device or the synaptic device depending on applications may be implemented to improve a degree of integration of the neuromorphic system.

In addition, the neuron device and the synaptic device may be co-integrated on the same plane using the same process to implement a highly integrated neuromorphic system. The neuromorphic system with a very high degree of integration may be implemented compared to the conventional neuromorphic system, in which a neuron circuit and a synaptic device array are manufactured through different processes and then are connected through wire bonding on a printed circuit board (PCB), and a low power and high performance neuromorphic system may be implemented because energy loss occurring in a signal transmission process between the neuron and the synapse, and interconnection delay and interference in wiring metal are minimized.

Referring to FIG. 5, a pre-synaptic neuron receives and integrates a current signal, and then when the value exceeds a specific threshold, a voltage signal in a spike form is transmitted to a synapse of a synapse array. Accordingly, the synapse of the synapse array having the pre-synaptic neuron and a post-synaptic neuron transmits a current signal, which reflects strength or weight of connection between the pre-synaptic neuron and the post-synaptic neuron, to the post-synaptic neuron.

The post-synaptic neuron integrates the current signals received from pre-synaptic devices, and then the voltage signal in the spike form is output when the value exceeds a specific threshold.

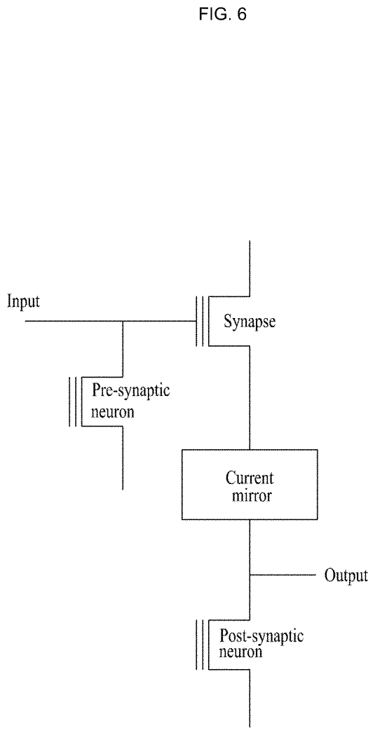

FIG. 6 illustrates a circuit diagram of a neuromorphic system using a single transistor usable as a neuron device and a synaptic device according to an embodiment of the present invention.

Specifically, FIG. 6 illustrates a circuit diagram of the neuromorphic system of FIG. 5 in which the neuron device and the synaptic device are co-integrated on the same plane using the same process using a single transistor capable of performing the neuron and synaptic operations according to an embodiment of the present invention.

Referring to FIG. 6, a neuron device corresponding to the pre-synaptic neuron of FIG. 5 receives a current signal through a source or drain, and outputs a voltage signal in a spike form to the source or drain when more than a certain current signal is collected. The source or drain of the neuron device is connected to a gate of a synaptic device in a post-synapse array, and thus transmits the voltage signal in the spike form to the gate of the synaptic device.

In addition, the synaptic device in the synapse array of FIG. 5 receives a voltage signal from the pre-neuron device (or pre-synaptic neuron) through the gate, and outputs a current signal to the source or drain. Here, the current signal varies depending on the weight of the synaptic device. For example, the source or drain of the synaptic device is connected to a source or drain of a post-neuron device to transmit a current signal reflecting the weight of the synaptic device to the post-neuron device.

In addition, the neuron device corresponding to the post-synaptic neuron of FIG. 5 receives and integrates a current signal through the source or drain from the pre-synaptic devices, and then, outputs the voltage signal in the spike form to the source or drain when more than a certain current signal is collected.

Referring to FIG. 6, a part where the voltage signal is transmitted from the source or drain of the neuron device to the gate of the synaptic device has a very large resistance when the gate of the synaptic device, and thus there is no load effect in which the voltage signal varies depending on a resistance state of the synaptic device.

Meanwhile, in a part where the current signal is transmitted from the source or drain of the synaptic device to the source or drain of the neuron device, because resistance when viewed from the source or drain of the neuron device continuously changes, a load effect in which the current signal varies depending on the resistance state of the neuron device occurs. Accordingly, an additional element such as a current mirror composed of two transistors may be required to transfer an output current from the source or drain of the synaptic device to the source or drain of the neuron device as it is.

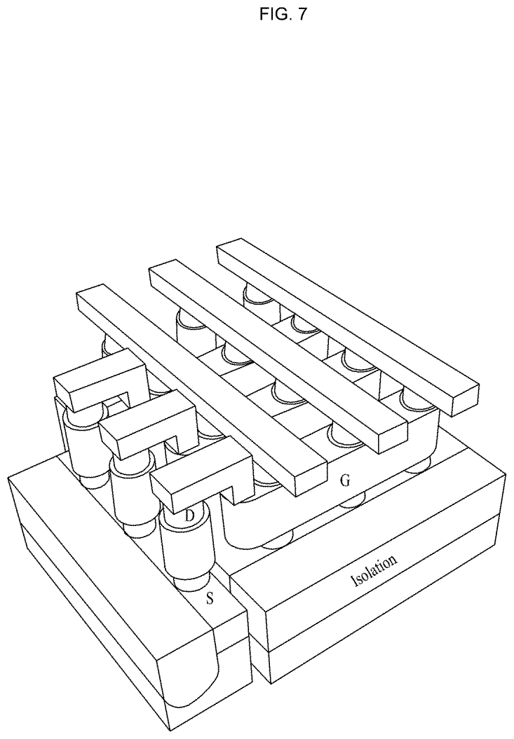

FIG. 7 illustrates a structure in which neurons and synapses are simultaneously implemented and connected on the same plane using a vertical transistor usable as a neuron device and a synaptic device according to an embodiment of the present invention.

In detail, FIG. 7 illustrates a structure in which a neuron and a synapse are co-integrated on the same plane and are connected by an interconnect metal using a single transistor capable of performing neuron and synaptic operations according to an embodiment of the present invention.

According to an embodiment of the present invention, using the single transistor, the neuron device and the synaptic device may be co-integrated on the same plane using the same process and may be connected by the interconnect metal to implement high integration neuromorphic system.

Here, the interconnection metal may be formed of any one of aluminum (Al), cobalt (Co), copper (Cu), tungsten (W), tin (TiN), titanium-tungsten (TiW), silicide (PtSi, TiSi₂, WSi₂, CoSi₂, NiSi), or any combination of thereof.

The highly integrated neuromorphic system according to an embodiment of the present invention may be suitable for off-chip learning in which a weight of the synaptic device does not need to be changed, but may be used for on-chip learning when an additional circuit changing the weight of the synaptic device is inserted to enable potentiation and depression of the synaptic device.

In addition, the highly integrated neuromorphic system according to an embodiment of the present invention may include one additional component or more of a resistor, a capacitor, and another transistor in addition to the single transistor usable as the neuron device and the synaptic device.

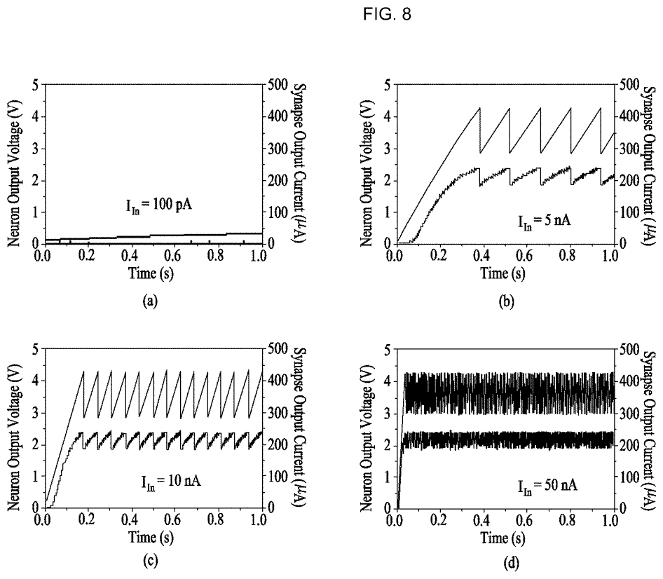

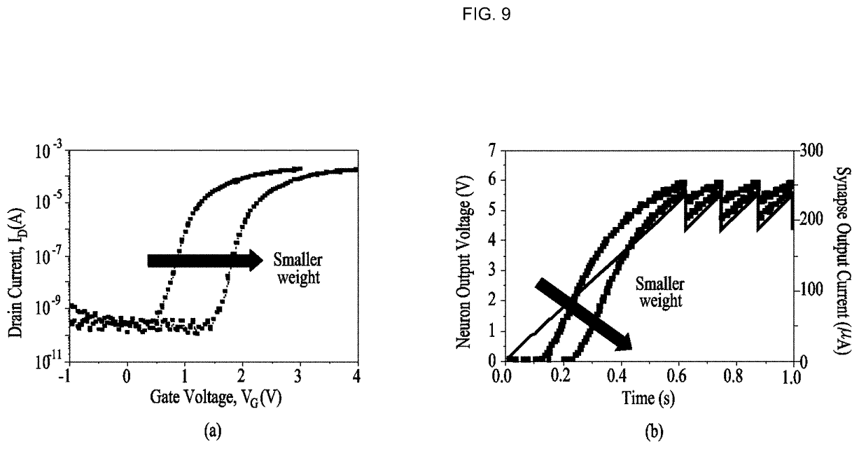

FIGS. 8 and 9 are graphs of electrical measurements of a neuromorphic system implemented using a vertical transistor usable as a neuron device and a synaptic device according to an embodiment of the present invention.

Specifically, FIGS. 8 and 9 are graphs of electrical measurements of the neuromorphic system of FIG. 5 in which two vertical transistors capable of performing a neuron operation and a synaptic operation, which are actually manufactured according to an embodiment of the present invention, respectively, are used as a neuron and a synapse to be implemented.

A vertical transistor including a floating body which was a vertical nanowire and had a diameter of 1280 nm is used as the neuron device. A vertical transistor including a floating body having a diameter of 400 nm is used as the synaptic device. Accordingly, when a constant current was input to a drain of the neuron device, a voltage output from the neuron device and a current of the synaptic device receiving the output voltage through a gate were measured.

Referring to FIG. 8, a line at a top of two graphs in FIGS. 8(a) to 8(d), that is, an upper line represents an output voltage of a neuron device and a line at a bottom of the two graphs, that is, a lower line represents an output current of a synaptic device receiving the output voltage.

It may be confirmed that, when a current hi input to the neuron device is 100 pA, both the output voltage of the neuron device and the output current of the synaptic device do not show a spike form, and when a current hi input to the neuron device is 5 nA or more, both the output voltage of the neuron device and the output current of the synaptic device show a spike form.

In addition, referring to FIG. 8, it is possible to confirm electrical characteristics of a typical neuromorphic system, in which frequency of the spike increases as the current Iₗₙ input to the neuron device increases.

Referring to FIG. 9, it is possible to confirm a graph showing characteristics in which, when a voltage signal of the same size is input from a pre-neuron device (or a pre-synaptic neuron), a magnitude of an output current of a synaptic device is varied depending on a weight of the synaptic device.

When more electrons are stored in a charge storage layer of the synaptic device, a drain current flowing for the same gate voltage is small as shown in FIG. 9(a), and thus the synaptic device has a small weight. Accordingly, it may be confirmed that, when the same voltage is input from the pre-neuron device (or pre-synaptic neuron), the magnitude of the output current of the synaptic device having the small weight is smaller as shown in FIG. 9(b), which shows the electrical characteristics of the typical neuromorphic system.

While the present invention has been described with reference to exemplary embodiments, it will be apparent to those skilled in the art that various changes and modifications may be made without departing from the spirit and scope of the present invention. Therefore, it should be understood that the above embodiments are not limiting, but illustrative. For example, suitable results may be achieved if the described techniques are performed in a different order, and/or if components in a described system, architecture, device, or circuit are combined in a different manner, and/or replaced or supplemented by other components or equivalents thereof.

Accordingly, other implementations, other embodiments, and equivalents of claims are within the scope of the following claims.

What is claimed is:

1. A single transistor usable as neuron and synaptic devices, the single transistor comprising:
a hole barrier material layer formed on a substrate and including a hole barrier material or an electron barrier material;
a floating body layer formed on the hole barrier material layer;
a source and a drain formed on opposite sides of the floating body layer;
a gate insulating layer formed on the floating body layer and including an oxide layer and a charge storage layer; and
a gate formed on the gate insulating layer.

2. The single transistor of claim 1, wherein the hole barrier material layer is formed of one of buried oxide, buried n-well in a case of a p-type body, buried p-well in a case of an n-type body, buried SiC, and buried SiGe.

3. The single transistor of claim 1, wherein the floating body layer accumulates holes generated by impact ionization and is formed of one of silicon, germanium, silicon germanium, and group 3-5 compound semiconductor.

4. The single transistor of claim 3, wherein the floating body layer has one structure of a planar-type floating body layer, a fin-type floating body layer, and a nanowire-type or nanosheet-type floating body.

5. The single transistor of claim 3, wherein the floating body layer is formed on the substrate in a horizontal direction or a vertical direction.

6. The single transistor of claim 1, further comprising:
a lower substrate formed below the floating body layer,
wherein the lower substrate operates as a back gate.

7. The single transistor of claim 1, wherein the source and drain are formed on left and right sides of the floating body layer in a case of a horizontal transistor and are formed above and below the floating body layer in a case of a vertical transistor, and are formed of one of n-type silicon, p-type silicon, and metal silicide.

8. The single transistor of claim 7, wherein the source and drain formed of the n-type silicon or the p-type silicon are formed by one of diffusion, solid-phase diffusion, epitaxial growth, selective epitaxial growth, ion implantation, and post-heat treatment.

9. The single transistor of claim 7, wherein the source and drain formed of the metal silicide are formed of one of erbium (Er), ytterbium (Yb), samarium (Sm), yttrium (Y), gadolium (Gd), turbule (Tb), cerium (Ce), platinum (Pt), lead (Pb), and iridium (Ir), and dopant segregation is used to improve junction.

10. The single transistor of claim 1, wherein the source and drain are formed in an asymmetrical structure of a concentration gradient to block a sneaky path of an array of the neuron and synapse.

11. The single transistor of claim 1, wherein the gate insulating layer includes two oxide layers positioned on opposite sides of the charge storage layer, or includes one oxide layer positioned on one side of the charge storage layer.

12. The single transistor of claim 1, wherein the gate has a gate-all-around structure surrounding the entire floating body layer.

13. The single transistor of claim 12, wherein the single transistor does not include the hole barrier material layer when having the gate-all-around structure.

14. The single transistor of claim 1, wherein the gate has a structure of a multiple-gate.

15. The single transistor of claim 1, wherein the single transistor, when a current signal is applied to the source and drain and the signal above a certain level is integrated, outputs a voltage signal in a spike form from the source and drain.

16. The single transistor of claim 1, wherein the single transistor, when a voltage signal is applied to the gate, outputs a current signal that changes depending on an amount of charges stored in the charge storage layer from the source and drain.

17. A highly-integrated neuromorphic system comprising:
a single transistor usable as a neuron device and a synaptic device,
wherein the neuron device and the synaptic device are co-integrated on the same plane using the same process and are connected using an interconnect metal to implement the neuromorphic system.

18. The highly-integrated neuromorphic system of claim 17, wherein the neuromorphic system is used for on-chip learning by inserting an additional circuit that changes a weight of the synaptic device.

19. The highly-integrated neuromorphic system of claim 17, wherein the neuromorphic system includes one additional component of a resistor, a capacitor, and another transistor, in addition to the single transistor.

20. A single transistor usable as neuron and synaptic devices comprising:
a source and a drain formed in an asymmetrical structure having a concentration gradient to block a sneaky path of a neuron and synapse array;
a floating body layer formed between the source and the drain and performing a neuron operation;
a gate insulating layer formed on the floating body layer and including a charge storage layer performing a synaptic operation; and
a gate formed on the gate insulating layer.
